(19) United States
(12) Patent Application Publication
(10) Pub. No.: US 2008/0053370 A1
(43) Pub. Date: Mar. 6, 2008

(54) Method for producing silicon single crystal

(76) Inventors: Shuichi Inami, Tokyo (JP); Kuniharu Inoue, Tokyo (JP); Manabu Moroishi, Tokyo (JP); Tsuguya Fukagawa, Tokyo (JP); Nobuhiro Kusaba, Tokyo (JP)

Correspondence Address: CLARK & BRODY, 1090 VERMONT AVENUE, NW, SUITE 250, WASHINGTON, DC, 20005, US

(21) Appl. No.: 11/896,564

(22) Filed: Sep. 4, 2007

(30) Foreign Application Priority Data
Sep. 5, 2006 (JP) 2006-240458

(51) Int. Cl. C30B 15/02

(52) U.S. Cl. 117/35

(57) ABSTRACT

An aspect of the invention provides a silicon single crystal production method in which a dislocation-free feature can easily be achieved to enhance crystal quality irrespective of a crystal orientation. In the silicon single crystal production method of the invention, by a Czochralski method, in dipping the seed crystal in the melt, a melt temperature is set to an optimum temperature at which the seed crystal is brought into contact with a melt surface, the melt temperature is lowered, the seed crystal is pulled up while a pulling rate of the seed crystal is increased, and the pulling rate is kept at a constant rate to form the neck portion at the time that a pulling diameter reaches a target neck diameter. The invention is suitable to the case in which a silicon single crystal having a crystal orientation <110> is pulled up using the seed crystal having the crystal orientation <110>.

### BACKGROUND OF THE INVENTION

1. Field of the Invention

The present invention relates to a method for producing a silicon single crystal by a Czochralski method (hereinafter referred to as “CZ method”), more particularly to the method for producing the silicon single crystal wherein crystal quality can be enhanced by improvement in a necking process of forming a neck portion subsequent to a dip process of dipping a seed crystal into a melt in a Dash method.

2. Description of the Related Art

Usually, in a configuration of a single crystal production apparatus used in the CZ method, a high-pressure resistant tightly-sealed chamber is evacuated to about 10 torr, an inert gas (Ar) is introduced into the chamber, and crystal raw materials are melted in a crucible provided in a lower portion of the chamber. Then, a seed crystal is dipped in a melt surface from above, and the seed crystal is pulled up while the crucible accommodating the seed crystal and the melt is rotated and vertically moved, thereby growing the silicon single crystal. The silicon single crystal includes a conical shoulder portion located below the seed crystal, a cylindrical body portion, and a conical tail portion whose lower end is projected.

In the growth method, at an initial pulling stage, after the dip process of dipping the seed crystal in the melt, the necking process of pulling the seed crystal to form a neck portion is performed.

FIGS. 1A and 1B are partially enlarged views schematically showing the dip process and necking process, which are performed in an initial stage of the CZ method, whereas FIG. 1A shows the dip process, and FIG. 1B shows the necking process. In the dip process shown in FIG. 1A, a seed crystal 1 is caused to move downward while rotated, and a leading end portion of the seed crystal 1 is dipped in a melt 2. After dipping the leading end portion of the seed crystal 1, the downward movement of the seed crystal 1 is halted and brought into contact with the melt surface.

When the seed crystal 1 is brought into contact with the melt surface, usually a meniscus is formed by a surface tension of the melt 2 at a contact interface between the seed crystal 1 and the melt 2. However, because a local melt temperature largely fluctuates immediately after crystal raw materials are melted, the temperature fluctuation is remarkably large as a whole, and the melt becomes an unstable state.

Therefore, the crystal raw materials are melted, and the dip process is performed after a sufficient time elapses. When the melt surface temperature becomes excessively high in bringing the seed crystal 1 into contact with the melt surface, the leading-end portion of the seed crystal 1 is melted away and separated from the melt 2. On the other hand, when the melt surface temperature becomes excessively low, the crystal is grown from the leading end portion of the seed crystal 1, and the crystal grows to hang over from the melt surface toward the melt 2. When the crystal growth is shifted into the neck formation, a new dislocation is generated in the neck portion.

Therefore, when the seed crystal is dipped into the melt in shifting from the dip process (see FIG. 1A) to the necking process (see FIG. 1B), it is necessary that the melt temperature be stabilized to an optimum temperature at which the seed crystal is brought into contact with the melt surface. Usually the operation for stabilizing the melt temperature at the optimum temperature is also called “fitting” of the seed crystal. A shape of a contact interface is observed to monitor the crystal hang-over when the seed crystal 1 is brought into contact with the melt 2, thereby estimating the melt surface temperature. A heater power is controlled based on the estimation to adjust input heat to the melt, which allows the melt temperature to be kept at the “optimum temperature” at which the seed crystal is brought into contact with the melt surface.

Specifically, to stabilize the melt temperature at the “optimum temperature”, the operation for adjusting the heater power to stabilize the melt surface temperature is required such that the meniscus 3 having a predetermined shape is formed around the leading end portion of the seed crystal 1 in the state in which a growth rate of the seed crystal 1 is zero.

The necking process shown in FIG. 1B is a process which obtains a dislocation-free single crystal. In the necking process, the seed crystal 1 is pulled up at a fast rate while rotated, the melt 2 is solidified on the leading end portion of the seed crystal 1, and a neck portion 4 is formed such that a diameter of a substantially cylindrical portion is reduced as small as possible. Although the required diameter depends on a thermal environment of the production apparatus, usually the neck portion 4 whose crystal diameter is reduced to a range of 4 to 6 mm approximately, which causes the dislocation to be removed. The method is also called Dash method or Dash-Neck method.

In forming the neck portion shown in FIG. 1B, because the single crystal having the reduced diameter is pulled up, the thermal environment in the production apparatus is liable to affect the process, and the control of growth conditions such as the pulling rate cannot respond to the rapid fluctuation in melt temperature Therefore, sometimes a trouble such as breakage failure of the neck portion is generated or sometimes the dislocation-free feature cannot be achieved. For this reason, conventionally various silicon single crystal production methods have been proposed.

For example, Japanese Patent No. 2822904 proposes a method, wherein a taper-like reduced portion next to the seed crystal is kept to have a length of 2.5 to 15 times the thickness of the seed crystal in pulling up the seed crystal, a longer-length, substantially-cylindrical reduced portion to follow the taper-like reduced portion is set to have the diameter of 0.09 to 0.9 times the thickness of the seed crystal, and the pull-up is performed such that a diameter fluctuation of the longer-length, substantially-cylindrical reduced portion ranges within 1 mm while the length thereof is kept in the range of 200 mm to 600 mm.

However, the method proposed in Japanese Patent No. 2822904 is intended to correspond to demands for the larger diameter and heavier weight of the silicon single crystal, and the dislocation-free feature can be achieved even if the diameter of the neck portion is enlarged in order to avert a risk of crystal fall due to the breakage failure of the neck portion. Accordingly, in the production method proposed in Japanese Patent No. 2822904, it takes a long time to form the neck portion, because not only the specific shape is required in a region from the seed crystal portion to the lower end of the neck portion but also ensuring a sufficient length is required to form neck portion. Additionally, because of constraint of the neck portion length, there arises a problem in that the body portion of the single crystal cannot sufficiently be ensured.

### SUMMARY OF THE INVENTION

As described above, in the case where the neck portion is formed by the Dash method, the seed crystal is brought into contact with the melt surface, the melt temperature is stabilized at the “appropriate temperature”, and the neck portion is formed at the lower end of the seed crystal while the seed crystal is raised at a predetermined fast rate. However, when the seed crystal is pulled up to form the neck portion at the “optimum temperature” at which the seed crystal is brought into contact with the melt surface, frequently the separation takes place between the seed crystal and the melt because of the excessively high melt temperature.

Therefore, even if the control is performed such that the melt temperature is lowered to a temperature suitable to the formation of the neck portion after the seed crystal pulling rate reaches a rate at which the target neck diameter is obtained, the melt temperature is adjusted by electric power output control to the electrical resistance heater, so that a time lag is generated until the temperature reaches the target melt temperature.

The seed crystal is pulled up at the temperature higher than the melt temperature suitable to the formation of the neck portion due to the time lag, which causes problems in that the neck portion of the target diameter cannot be formed and the single crystal cannot be grown because of the generation of the separation between the seed crystal and the melt.

In order to avoid the separation, alternatively the pull-up of the seed crystal is halted until the melt temperature reaches the temperature suitable to the formation of the neck portion, and the seed crystal is pulled up after the melt temperature reaches the temperature suitable to the formation of the neck portion. However, liquid covering occurs in an outer peripheral portion of the seed crystal before the melt temperature reaches the temperature suitable to the formation of the neck portion, which causes the generation of the dislocation to affect the crystal quality.

Recently, a silicon wafer having a plane orientation (110) receives widespread attention. Because carrier mobility depends largely on a crystal orientation when the semiconductor element is formed, enhancement of a switching speed of the semiconductor element for achieving high speed mobility of the semiconductor element can be expected in the silicon wafer having a plane orientation (110).

In pulling up the silicon single crystal having the crystal orientation <100> or <111>, the slip dislocation can be removed from the grown crystal by narrowing down the crystal diameter as long as the slip dislocation caused by the thermal shock is slightly generated at the leading end of the seed crystal. However, in the silicon single crystal having the crystal orientation <110>, the slip dislocation enters neighbors in a direction substantially perpendicular to the melt surface of the seed crystal, so that even if benign slip dislocations are generated in the seed crystal, there is a problem in that the slip dislocations are hardly eliminated.

In view of the foregoing, an object of the invention is to provide a silicon single crystal production method in which, in pulling up the silicon single crystals having the crystal orientations <100> or <111> and <110>, the dislocation-free can easily be achieved to enhance the crystal quality irrespective of the crystal orientation by improving the dip process of dipping the seed crystal in the melt and the necking process of forming the neck portion in the Dash method.

As the results of various studies for solving the above problems, the inventors paid attention to the crystal quality improving method in which, in the Dash method shown in FIGS. 1A and 1B, the generation of the benign slip dislocation is eliminated by simultaneously performing the operation for lowering the melt temperature and the operation for increasing the pulling rate of the seed crystal after the optimum temperature at which the seed crystal is brought into contact with the melt surface is obtained.

The present invention is completed based on the findings above and its gist pertains to a silicon single crystal production method below.

(1) A silicon single crystal production method according to a CZ Method, in which a shoulder portion and a body portion of the single crystal are formed subsequent to a necking process where crystal raw materials in a crucible are melted, and a seed crystal is dipped in a melt retained in the crucible and is pulled up to form a neck portion, wherein, in dipping the seed crystal in the melt, a melt temperature is set to an optimum temperature at which the seed crystal is brought into contact with a melt surface, the melt temperature is lowered, the seed crystal is pulled up while a pulling rate of the seed crystal is increased, and the pulling rate is kept at a constant rate to form the neck portion at the time that a pulling diameter reaches a target neck diameter.

In the silicon single crystal production method as above, preferably the melt temperature is lowered by an extent in a range of 3 to 4° C., the pulling rate of the seed crystal is increased in a range of 0 to 5 mm/min.

(2) A silicon single crystal production method according to (1), wherein preferably a diameter in a lower portion of the seed crystal which is brought into contact with the melt surface is not more than 8 mm, and a diameter of the formed neck portion ranges from 4 to 6 mm, and further the method being recognized as a best suitable method for pulling a silicon single crystal having a crystal orientation <110> using the seed crystal having the crystal orientation <110>.

According to the silicon single crystal production method of the present invention, in pulling up the silicon single crystals having the crystal orientations <100> or <111> and <110>, the dislocation-free feature can easily be achieved to enhance the crystal quality irrespective of the crystal orientation by improving the dip process of dipping the seed crystal in the melt and the necking process of forming the neck portion in the dash method. Therefore, the production cost is largely reduced, and the invention can widely be applied as the efficient Dash method.

### BRIEF DESCRIPTION OF THE DRAWINGS

FIGS. 1A and 1B are partially enlarged views schematically showing a dip process and a necking process, which are performed in an initial stage of a CZ method, whereas FIG. 1A shows the dip process, and FIG. 1B shows the necking process;

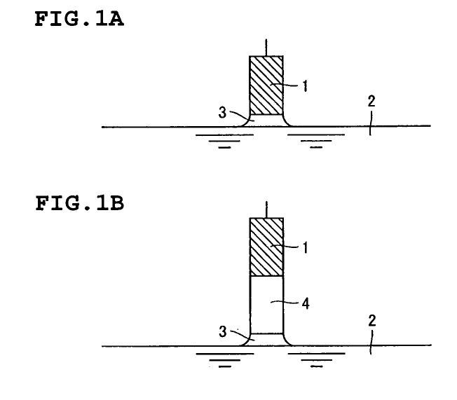

FIG. 2 shows an example of appearance of the neck portion formed by a silicon single crystal production method according to an exemplary embodiment of the invention.

### DETAILED DESCRIPTION OF THE PREFERRED EMBODIMENTS

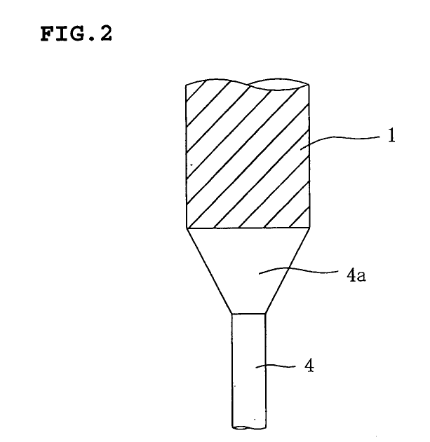

FIG. 2 shows an example of appearance of the neck portion formed by a silicon single crystal production method according to an exemplary embodiment of the invention. In the neck portion 4 formed through the dip process and necking process according to the invention, the reduced portion 4a whose diameter is successively shrunk is formed in a lower end portion of the seed crystal 1, and the neck portion 4 having the target diameter is formed underneath the reduced portion 4a.

In feature of the silicon single crystal production method of the invention, when the crystal raw materials in the crucible are melted to dip the seed crystal into the melt in the crucible by the CZ method, after the melt temperature is set to the optimum temperature at which the seed crystal is brought into contact with the melt surface, the melt temperature is lowered, the seed crystal is pulled up while the pulling rate is increased, and the neck portion is formed by setting the pulling rate to a constant rate at the time that the pulling diameter reaches the target neck diameter.

In the silicon single crystal production method of the invention, because the transition is made to the dip process after the crystal raw materials in the crucible are melted, in dipping the seed crystal into the melt of the crucible, it is necessary that the melt temperature be set to the optimum temperature at which the seed crystal is brought into contact with the melt surface.

As used herein, “the optimum temperature at which the seed crystal is brought into contact with the melt surface” shall mean the melt temperature stabilized by the so-called “seed crystal fitting” operation, and “the optimum temperature at which the seed crystal is brought into contact with the melt surface” means the temperature of the melt surface in which the meniscus shape at the contact interface, e.g., the hang-over of a crystal-laiden line is observed to estimate the melt surface temperature, the heater power (electric power) is controlled based on the estimation, and the input heat to the melt are adjusted to stabilize the melt surface. In the specific operation, in the state in which the growth rate of the seed crystal 1 is zero, the heater power is adjusted to stabilize the melt surface temperature such that the meniscus 3 having the predetermined shape is formed around the leading end portion of the seed crystal 1.

The temperature at which the melt temperature is stabilized depends on the pulling apparatus used, and the temperature at which the melt temperature is stabilized varies when the seed crystal diameter or target neck diameter varies even in the same pulling apparatus. Therefore, “the optimum temperature at which the seed crystal is brought into contact with the melt surface” defined in the invention cannot uniquely be determined.

Accordingly, in the silicon single crystal production method of the invention, it is necessary that the “optimum temperature” be correctly acquired to control the melt temperature. Usually, a method for controlling the melt temperature is adapted such that the heater power (electric power) is adjusted to control the heater temperature based on data obtained by optically measuring the melt temperature.

However, in a method for measuring the melt surface temperature using means for optically measuring the temperature such as a single-color thermometer and a two-color thermometer, the temperature measurement is easily affected by a disturbance factor such as SiO evaporation generated in growing the crystal, and the measured temperature varies depending on a measurement point of the melt surface due to the influence of melt heat convection. Therefore, the measured temperature has poor reliability, and the measured temperature cannot be applied to the Dash method in which the precise temperature control is required.

In the silicon single crystal production method of the invention, desirably the heater temperature at which the crystal raw materials in the crucible are melted is measured, and the melt temperature is adjusted by adjusting heater power (electric power) to control the heater temperature based on the temperature measurement result. The heater temperature corresponds to the melt temperature one-on-one, and the heater temperature is not affected by the disturbance factor such as the SiO evaporation or the melt heat convection even if the heater temperature is measured with the radiation thermometer or the two-color thermometer, so that the melt temperature can correctly be measured as the optimum temperature at which the seed crystal is brought into contact with the melt surface.

In the silicon single crystal production method of the invention, it is mandatory that after the melt temperature is set to the optimum temperature at which the seed crystal is brought into contact with melt surface, the melt temperature is lowered, and the pull-up is performed while the pulling rate of the seed crystal is enhanced.

Even in the state in which a temperature distribution of the melt is stabilized, when the melt temperature is kept at the optimum temperature at which the seed crystal is brought into contact with melt surface, the neck portion having the target diameter cannot be formed because the melt temperature is in the higher state, or the neck portion cannot be grown because the severance is generated between the seed crystal and the melt. Therefore, it is necessary that the melt temperature be lowered to the temperature suitable to the formation of the neck portion, and the melt temperature is lowered by decreasing the heater power (electric power) to control the heater temperature. At this point, desirably the melt temperature is lowered by an extent in the range of 4 to 5° C.

As described above, even if the heater power for heating the crystal raw materials in the crucible is lowered to start the heater temperature control, the time lag is generated until the melt temperature reaches the temperature suitable to the formation of the neck portion, and the liquid covering is generated in the outer peripheral portion of the seed crystal before the melt temperature reaches the temperature suitable to the formation of the neck portion, which sometimes causes the generation of the dislocation. In this regard, in the silicon single crystal production method of the invention, the liquid covering is not generated in the outer peripheral portion of the seed crystal by pulling the seed crystal while the pulling rate of the seed crystal is increased.

Because the pulling rate which can be applied to the formation of the neck portion also depends on a hot zone structure (temperature distribution inside a crucible) of the growing apparatus, the pulling rate cannot quantitatively be determined. According to studies of the inventors, in pulling up the silicon single crystal having a diameter of 300 mm, the pull-up is effectively performed while the pulling rate is gradually increased in the range of 0 to 5 mm/min. Although desirably the pulling rate is linearly increased, the pulling rate may be increased in a step manner of a short time duration.

Accordingly, in the silicon single crystal production method of the invention, desirably the melt temperature is lowered by an extent in the range of 3 to 4° C., and the seed crystal is pulled up while the pulling rate of the seed crystal is gradually increased in the range of 0 to 5 mm/min. Thus, the melt temperature is lowered by an extent in the range of 3 to 4° C., and the seed crystal is pulled up while the pulling rate of the seed crystal is gradually increased. Therefore, the reduced portion 4a whose diameter is successively shrunk is formed in the lower end portion of the seed crystal shown in FIG. 2, and the liquid covering to be generated in the outer peripheral portion of the seed crystal 1 can be prevented.

In the silicon single crystal production method of the invention, the pulling rate is set to a constant rate at the time that pulling diameter reaches the target neck diameter, and the neck portion is formed as shown in FIG. 2. Desirably the target neck diameter of the invention ranges from 4 to 6 mm. This is because the slip dislocation generated in the seed crystal is effectively removed while the strength of the neck portion can be ensured corresponding to the larger diameter and heavier weight of the pulled single crystal.

In the seed crystal used in the silicon single crystal production method of the invention, a crystal diameter of the lower end portion thereof which is in contact with the melt surface is set to 8 mm or less. Usually, the seed crystal diameter ranges from 20 to 10 mm, and a highly sophisticated technique is required to form the reduced portion to narrow down the reduced portion to the neck portion target diameter ranging from 3 to 6 mm. In dipping the seed crystal in the melt, the fluctuation in melt temperature becomes large. Therefore, in order to stabilize the melt temperature distribution while the strength of the neck portion is secured, the crystal diameter of the lower end portion which is in contact with the melt surface can be set to 8 mm or less.

The silicon single crystal production method of the invention is suitable to the case in which the seed crystal having the crystal orientation <110> is used to pull up the silicon single crystal having the crystal orientation <110>. As described above, when compared with the seed crystal having the crystal orientation <100>, from the standpoint of the crystal structure, the seed crystal having the crystal orientation <110> includes a crystal plane {111} which is a slip plane parallel to the pulling axial direction. Therefore, the dislocation generated in the seed crystal resulting from the contact with the melt surface hardly escapes out of the seed crystal, and the dislocation is taken over to the grown crystal through the neck portion. However, in the present invention, when the seed crystal is dipped in the melt, the melt temperature is set to the optimum temperature at which the seed crystal is brought into contact with the melt surface, whereby the generation of a thermal strain caused by the dip of the seed crystal can be eliminated as much as possible to suppress the generation of the slip dislocation.

### EXAMPLES

The advantages of the silicon single crystal production method according to the present invention will be described based on Examples in which the specific process is applied. In Examples, the 8-inch silicon single crystals having the crystal orientations <100> and <110> respectively are grown, and a test of a dislocation-free ratio is performed.

First the 140-kg polycrystalline silicon materials which are the crystal raw materials are loaded in the 24-inch quartz crucible, and the crystal raw materials in the crucible are melted. At the stage in which the transition is made to the dip process using the seed crystal having the crystal orientation <100>, the downward movement of the seed crystal is tentatively halted before the seed crystal is dipped in the melt, and the seed crystal is pre-heated to increase the temperature of the seed crystal, which releases the thermal shock (heat shock) caused by the contact with the melt surface. Then, the seed crystal moves downward while rotated, the downward movement of the seed crystal is halted, and the fitting operation is performed to achieve the stabilization such that the melt temperature becomes the optimum temperature at which the seed crystal is brought into contact with the melt surface.

After observing that the predetermined meniscus shape is formed at the lower end of the seed crystal, the melt temperature is lowered by 4 to 5° C. to adjust the heater power such that the melt temperature becomes the temperature suitable to the formation of the neck portion. The operation for pulling up the seed crystal is started at the same time of starting the heater power control, and the target diameter of 5 mm is obtained in the neck portion while the pulling rate is gradually increased from 0 mm/min. After the target diameter is obtained in the neck portion, the neck portion is formed at the constant pulling rate of 5 mm/min, and the shoulder portion, the body portion, and the tail portion are successively pulled up.

The test of the dislocation-free ratio is performed for the 20 silicon single crystals thus pulled up, and the dislocation-free ratio of 90% (18 are good out of 20 silicon single crystals) is obtained.

Then, the silicon single crystal having the crystal orientation <110> is pulled up using the seed crystal having the crystal orientation <110>, and the test of the dislocation-free ratio is performed. Similarly, the 140-kg polycrystalline silicon materials which are the crystal raw materials are loaded in the 24-inch quartz crucible, and the crystal raw material in the crucible is melted.

In the dip process, after the seed crystal is pre-heated, the seed crystal moves downward while rotated, and the seed crystal is dipped in the melt. Then, the downward movement of the seed crystal is halted to perform the fitting operation, and the fitting operation is performed to achieve the stabilization such that the melt temperature becomes the optimum temperature at which the seed crystal is brought into contact with the melt surface.

After observing that the predetermined meniscus shape is formed at the lower end of the seed crystal, while the melt temperature is lowered by 4 to 5° C. to adjust the heater power such that the melt temperature becomes the temperature suitable to the formation of the neck portion, the operation for pulling up the seed crystal is started. Then, the target diameter of 5 mm is obtained in the neck portion while the pulling rate is gradually increased from 0 mm/min to 5 mm/min. After the target diameter is obtained in the neck portion, the neck portion is formed at the constant pulling rate of 5 mm/min, and the shoulder portion, the body portion, and the tail portion are successively pulled up.

The test of the dislocation-free ratio is performed for the 18 silicon single crystals thus pulled up, and the dislocation-free ratio of 83% (15 are good out of 18 silicon single crystals) is obtained.

According to the silicon single crystal production method of the invention, in pulling up the silicon single crystals having the crystal orientations <100> or <111> and <110>, the generation of the slip dislocation is suppressed, and the dislocation-free can easily be achieved to enhance the crystal quality irrespective of the crystal orientation by improving the dip process of dipping the seed crystal in the melt and the necking process of forming the neck portion in the Dash method. Therefore, the production cost is largely reduced, and the invention can widely be applied as the efficient Dash method.

What is claimed is:

1. A silicon single crystal production method in which, by a Czochralski method, a shoulder portion and a body portion of the single crystal are formed subsequent to a necking process where crystal raw materials in a crucible are melted, and a seed crystal is dipped in a melt retained in the crucible and is pulled up to form a neck portion,
wherein, in dipping the seed crystal in the melt, a melt temperature is set to an optimum temperature at which the seed crystal is brought into contact with a melt surface, the melt temperature is lowered, the seed crystal is pulled up while a pulling rate of the seed crystal is increased, and the pulling rate is kept at a constant rate to form the neck portion at the time that a pulling diameter reaches a target neck diameter.

2. The silicon single crystal production method according to claim 1, wherein the melt temperature is lowered by an extent in a range of 3 to 4° C., the pulling rate of the seed crystal is increased in a range of 0 to 5 mm/min.

3. The silicon single crystal production method according to claim 1, wherein a diameter in a lower portion of the seed crystal which is brought into contact with the melt surface is not more than 8 mm, and a diameter of the formed neck portion ranges from 4 to 6 mm.

4. The silicon single crystal production method according to claim 1, wherein a silicon single crystal having a crystal orientation <110> is pulled up using the seed crystal having the crystal orientation <110>.

5. The silicon single crystal production method according to claim 2, wherein a silicon single crystal having a crystal orientation <110> is pulled up using the seed crystal having the crystal orientation <110>.

6. The silicon single crystal production method according to claim 3, wherein a silicon single crystal having a crystal orientation <110> is pulled up using the seed crystal having the crystal orientation <110>.
